(19) United States
(12) Patent Application Publication
(10) Pub. No.: US 2013/0320411 A1
(43) Pub. Date: Dec. 5, 2013

(54) BORDERLESS CONTACTS FOR METAL GATES THROUGH SELECTIVE CAP DEPOSITION

(71) Applicants: Su-Chen Fan, Cohoes, NY (US); Balasubramanian S. Haran, Watervliet, NY (US); David V. Horak, Essex Junction, VT (US); Shom Ponoth, Clifton Park, NY (US); Chih-Chao Yang, Glenmont, NY (US)

(72) Inventors: Su-Chen Fan, Cohoes, NY (US); Balasubramanian S. Haran, Watervliet, NY (US); David V. Horak, Essex Junction, VT (US); Shom Ponoth, Clifton Park, NY (US); Chih-Chao Yang, Glenmont, NY (US)

(73) Assignee: International Business Machines Corporation, Armonk, NY (US)

(21) Appl. No.: 13/488,581

(22) Filed: Jun. 5, 2012

(51) Int. Cl. H01L 21/336; H01L 29/78

(52) U.S. Cl. 257/288; 438/299; 257/E29.255; 257/E21.409

(57) ABSTRACT

A semiconductor device including a gate structure present on a channel portion of a substrate, in which the gate structure includes at least one high-k gate dielectric layer and at least one metal gate conductor. A source region and a drain region is present on opposing sides of the channel portion of the substrate. A metal oxide gate cap is present on an upper surface of the metal gate conductor. The metal oxide composition of the metal oxide gate cap may be zirconium oxide, aluminum oxide, magnesium oxide, hafnium oxide or a combination thereof. Contacts may extend through an intralevel dielectric layer into contact with at least one of the source region and the drain region.

### BACKGROUND

The present disclosure relates to forming contacts to semiconductor structures.

For more than three decades, the continued miniaturization of silicon metal oxide semiconductor field effect transistors (MOSFETs) has driven the worldwide semiconductor industry. Various showstoppers to continued scaling have been predicated for decades, but a history of innovation has sustained Moore's Law in spite of many challenges. However, there are growing signs today that metal oxide semiconductor transistors are beginning to reach their traditional scaling limits. Since it has become increasingly difficult to improve MOSFETs and therefore complementary metal oxide semiconductor (CMOS) performance through continued scaling, further methods for improving performance in addition to scaling have become critical.

### SUMMARY

In one embodiment, a method of forming contacts to a semiconductor device is provided that includes providing a gate structure having a metal gate conductor on a channel portion of a substrate. An intralevel dielectric is then formed on the substrate and adjacent to the gate structure, wherein an upper surface of the intralevel dielectric is coplanar with an upper surface of the metal gate conductor of the gate structure. A metal gate cap is formed on the upper surface of the metal gate conductor. A dielectric cap is then formed on the intralevel dielectric. The metal gate cap is then removed selectively to the dielectric cap and the metal gate conductor to provide a void overlying the metal gate conductor. The void that is present over the metal gate conductor may then be filled with a metal oxide cap. The metal oxide cap that fills the void over the metal gate conductor provides an etch mask to protect the gate structure. The dielectric conductor of the gate structure and the intralevel dielectric may then be etched using an etch chemistry that is selective to the metal oxide cap to provide an opening to at least one of a source region and a drain region that is present on opposing sides of the channel portion of the substrate. A metal fill can be formed within the opening provides a contact to said at least one of the source region and the drain region.

In another embodiment, a method of forming contacts to a semiconductor device is provided that includes providing a gate structure having a metal gate conductor on the channel portion of a substrate. An intralevel dielectric is then formed on the substrate and adjacent to the gate structure, wherein an upper surface of the intralevel dielectric is coplanar with an upper surface of the metal gate conductor of the gate structure. A metal gate cap is formed on the upper surface of the metal gate conductor. The metal gate cap may be oxidized to provide a metal oxide cap. The intralevel dielectric may then be etched using an etch chemistry that is selective to the metal oxide cap to provide an opening to at least one of a source region and a drain region that is present on opposing sides of the channel portion of the substrate. A metal fill formed within the opening provides a contact to at least one of the source region and the drain region.

In another aspect, a semiconductor device is provided that includes a gate structure present on a channel portion of a substrate, in which the gate structure includes at least one high-k gate dielectric layer and at least one metal gate conductor. A source region and a drain region are present on opposing sides of the channel portion of the substrate. A metal oxide gate cap is present on an upper surface of the at least one metal gate conductor. The metal oxide composition of the metal oxide gate cap is selected from the group consisting of zirconium oxide, aluminum oxide, magnesium oxide, hafnium oxide and a combination thereof. Contacts extend through an intralevel dielectric layer into contact with at least one of the source region and the drain region.

### BRIEF DESCRIPTION OF THE DRAWINGS

The following detailed description, given by way of example and not intended to limit the disclosed methods and structures solely thereto, will best be appreciated in conjunction with the accompanying drawings, wherein like reference numerals denote like elements and parts, in which:

FIG. 1 is a side cross-sectional view of forming replacement gate structures on a substrate, in accordance with one embodiment of the present disclosure.

FIG. 2 is a side cross-sectional view of removing the replacement gate structures to provide openings to channel portions of the substrate, in accordance with one embodiment of the present disclosure.

FIG. 3 is a side cross-sectional view of forming functional gate structures in the openings to the channel portions of the substrate, in accordance with one embodiment of the present disclosure.

FIG. 4 is a side cross-sectional view depicting planarizing the material layers that provide the functional gate structures until the upper surface of the functional gate structures are coplanar with an upper surface of intralevel dielectrics that are adjacent to the functional gate structures, in accordance with one embodiment of the present disclosure.

FIG. 5 is a side cross-sectional view of recessing the intralevel dielectrics selectively to the functional gate structures, in accordance with one embodiment of the present invention.

FIG. 6 is a side cross-sectional view of depositing a metal for metal gate caps on the upper surface of the functional gate structures and an upper surface of the intralevel dielectrics, in accordance with one embodiment of the present disclosure.

FIG. 7 is a side cross-sectional view of removing the metal that is present on intralevel dielectrics, wherein the remaining portion of the metal provides the metal gate cap and is present on the function gate structures, in accordance with one embodiment of the present disclosure.

FIG. 8 is a side cross-sectional view of forming a dielectric capping layer on the recessed upper surfaces of the intralevel dielectrics, in accordance with one embodiment of the present disclosure.

FIG. 9 is a side cross-sectional view of removing the metal gate caps, in accordance with one embodiment of the present disclosure.

FIG. 10 is a side cross-sectional view of filling the voids that are formed by removing the metal gate caps that are present over the functional gate structures with metal oxide caps, in accordance with one embodiment of the present disclosure.

FIG. 11 is a side cross-sectional view depicting etching the dielectric caps and the intralevel dielectrics using an etch chemistry that is selective to the metal oxide caps to provide at least one opening to at least one of a source region and a drain region that is present on opposing sides of the channel portion of the substrate, and filling the openings with a metal, in accordance with one embodiment of the present disclosure.

FIG. 12 is a side cross-sectional view of oxidizing the metal gate caps to provide metal oxide caps that are present on the upper surfaces of the functional gate structures, in accordance with one embodiment of the present disclosure.

### DETAILED DESCRIPTION

Detailed embodiments of the present disclosure are described herein; however, it is to be understood that the disclosed embodiments are merely illustrative of the present disclosure that may be embodied in various forms. In addition, each of the examples given in connection with the various embodiments of the disclosure are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the present disclosure. For purposes of the description hereinafter, the terms “upper”, “lower”, “vertical”, “horizontal”, “top”, “bottom”, and derivatives thereof shall relate to the invention, as it is oriented in the drawing figures.

As semiconductor and electrical device technologies move to smaller and smaller dimensions, the traditional space for substrate contacts in logic devices is decreasing. In some examples, it is anticipated that the contact will impinge on the area between the side of the gate conductor and the edge of the source region or the drain region. More specifically, and in some examples, the over-etch for forming the contacts to the source regions and drain regions that can be required to avoid open chain yields may have an adverse impact on the region of the semiconductor substrate between the gate structure and the source and drain regions. In one scenario, the contact to one of the source region and the drain region might also contact the gate conductor thereby shorting the device.

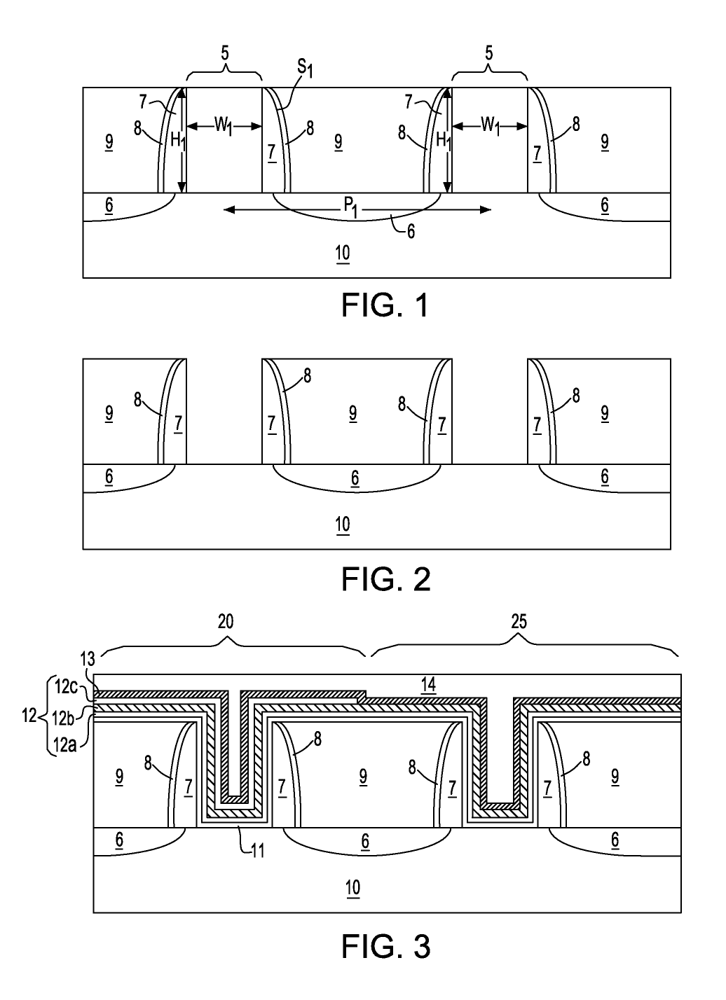

In one embodiment, the present disclosure may provide a borderless contact integration scheme for replacement gate methods. In some embodiments, the methods and structures that are disclosed herein rely on forming material layers composed of an etch stop material, e.g., metal oxide etch stop material, that protect both the gate structure, e.g., gate conductor, and also the spacer that is adjacent to the gate structure during the etch process that forms the openings for the contacts to the source region and the drain region. FIGS. 1-11 depict one embodiment of a method of forming semiconductor devices that employs etch stop materials, e.g., metal oxide etch stop materials, during the process sequence for forming contacts to the source regions and drain regions of the semiconductor device. As used herein, a “semiconductor device” is an intrinsic semiconductor material that has been doped, i.e., into which a doping agent has been introduced, giving it different electrical properties than the intrinsic semiconductor. Although, the semiconductor devices that are provided in the supplied figures are field effect transistors (FETs), the present disclosure is not limited to only this example, as any semiconductor device that may be shorted by forming contacts to the device is applicable to the structures and methods disclosed herein.

FIG. 1 depicts forming sacrificial gate structures 5 (also referred to as replacement gate structures) on channel portions of a substrate 10. The substrate 10 may be any silicon-containing substrate including, but not limited to, Si, bulk Si, single crystal Si, polycrystalline Si, SiGe, amorphous Si, silicon-on-insulator substrates (SOI), SiGe-on-insulator (SGOI), strained-silicon-on-insulator, annealed poly Si, and poly Si line structures. The substrate 10 may also include a first doped (n- or p-) region, and a second doped (n- or p-) region. For clarity, the doped regions are not specifically labeled in the drawings of the present application. These doped regions are known as “wells”. The substrate 5 may also be composed of compound semiconductor materials, such as type III-V semiconductor.

The sacrificial gate structures 5 each include a sacrificial material that defines the geometry of a later formed functional gate structures, which function to switch the semiconductor devices from an “on” to “off' state, and vice versa. In one embodiment, and as illustrated in FIG. 1, each of the sacrificial gate structures 5 may be composed of a single layer of sacrificial material. In another embodiment, each of the sacrificial gate structures 5 includes a sacrificial material stack (not depicted) on the substrate 10, in which the sacrificial material stack may be composed of a plurality of layers of sacrificial material.

In one embodiment, the sacrificial gate structures 5 may be composed of a semiconductor-containing material, such as a silicon-containing material. Silicon-containing materials that are suitable for the sacrificial gate structures 5 include, but are not limited to, silicon (Si), single crystal silicon, polycrystalline silicon, amorphous silicon, SiO₂, Si₃N₄, SiOₓN_{y}, SiC, SiCO, Si—COH, SiCN and SiCH compounds, and the above-mentioned silicon-containing materials with some or all of the Si replaced by Ge. In one example, the sacrificial material that provides the sacrificial gate structures 5 is amorphous silicon. In some embodiments, other materials, such as dielectrics and metals, can be employed as the sacrificial material of the sacrificial gate structures 5, so long as the material selected can be removed selective to the substrate 10 and the subsequently formed intralevel dielectrics.

The sacrificial material layer that provides the sacrificial gate structures 5 may be formed using a deposition process, such as chemical vapor deposition (CVD). Chemical vapor deposition (CVD) is a deposition process in which a deposited species is formed as a result of chemical reaction between gaseous reactants at an elevated temperature (typically greater than 200° C.), wherein a solid product of the reaction is deposited on the surface on which a film, coating, or layer of the solid product is to be formed. Variations of CVD processes include, but not limited to, Atmospheric Pressure CVD (APCVD), Low Pressure CVD (LPCVD) and Plasma Enhanced CVD (PECVD), Metal-Organic CVD (MOCVD) and combinations thereof may also be employed. The sacrificial material may also be deposited using evaporation, chemical solution deposition, spin on deposition, and physical vapor deposition (PVD) methods.

The sacrificial material may be patterned and etched to provide the sacrificial gate structures 5. Specifically, and in one example, a pattern is produced by applying a photoresist to the surface to be etched, exposing the photoresist to a pattern of radiation, and then developing the pattern into the photoresist utilizing a resist developer. Once the patterning of the photoresist is completed, the sections covered by the photoresist are protected, while the exposed regions are removed using a selective etching process that removes the unprotected regions. As used herein, the term “selective” in reference to a material removal process denotes that the rate of material removal for a first material is greater than the rate of removal for at least another material of the structure to which the material removal process is being applied.

In one embodiment, the etch process removes the exposed portions of the sacrificial material layer with an etch chemistry that is selective to the substrate 10. In another embodiment, the etch process that forms the sacrificial gate structures 5 is an anisotropic etch. An anisotropic etch process is a material removal process in which the etch rate in the direction normal to the surface to be etched is greater than in the direction parallel to the surface to be etched. The anisotropic etch may include reactive-ion etching (RIE). Other examples of anisotropic etching that can be used at this point of the present disclosure include ion beam etching, plasma etching or laser ablation.

The width W1 of each of the sacrificial gate structures 5 may range from 20 nm to 250 nm. In another embodiment, the width W1 of each of the sacrificial gate structures 5 may range from about 50 nm to 150 nm. In yet another embodiment, the width W1 of each the sacrificial gate structure 5 may range from 80 nm to 100 nm. The height H1 for each of the sacrificial gate structures 5 may range from 50 nm to 500 nm. In another embodiment, the height H1 for each of the sacrificial gate structures 5 may range from about 100 nm to about 200 nm. In yet another embodiment, the height H1 for each of the sacrificial gate structures 5 may range from 125 nm to 175 nm.

The spacing between adjacent sacrificial gate structures 5 dictates the pitch P1 of the subsequently formed functional gate structures. The term “pitch” means the center-to-center distance between two repeating elements of a circuit including semiconductor devices. In one embodiment, the pitch P1 may be measured from the center of the upper surface of a first sacrificial gate structure to the center of the upper surface of an adjacent sacrificial gate structure. The actual dimensions for the pitch may depend upon the technology node. In one example, the gate pitch is selected to correspond to the 20 nm technology node. In this example, the gate pitch P1 ranges from 50 nm to 100 nm.

In a following process step, source and drain extension regions 6 may be formed in the substrate 10 and partially extend under each of the sacrificial gate structures 5. Source and drain extension regions 6 are formed via ion implantation. In one embodiment, p-type conductivity semiconductor devices are produced within Si-containing substrates 10 by doping the source and drain extension regions 6 with elements from group III-A of the Periodic Table of Elements. The n-type conductivity semiconductor devices are produced within Si-containing substrates by doping the source and drain extension regions 6 with elements from group V-A of the Periodic Table of Elements. In the embodiment that is depicted in FIG. 1, a plurality of semiconductor devices having the same conductivity type are formed on the same substrate 10, in which the adjacent semiconductor devices have a shared source and drain extension region 6. In another embodiment, semiconductor devices of different conductivity type may be formed on the same substrate 10 and are isolated from semiconductor devices of opposing conductivity type with isolation regions, such as shallow trench isolation regions. In these embodiments, the source and drain extension regions that are formed to a first conductivity type semiconductor device, e.g., n-type conductivity, are separated from the source and drain extension regions of a second conductivity type semiconductor device, e.g., p-type conductivity, by an isolation region, such as a shallow trench isolation (STI) region.

Referring to FIG. 1, a dielectric spacer 7 can be formed abutting the sidewall surface of each of the sacrificial gate structures 5. The dielectric spacer 7 may be composed of any dielectric material. In one embodiment the dielectric spacer 7 may be composed of a nitride, oxide or oxynitride material. For example, the dielectric spacer 7 may be composed of silicon nitride. In another example, the dielectric spacer 7 may be composed of silicon oxide. Other examples of materials suitable for the dielectric spacer 7 include organosilicate glass (OSG), fluorine doped silicon dioxide, carbon doped silicon dioxide, porous silicon dioxide, porous carbon doped silicon dioxide, spin-on organic polymeric dielectrics (e.g., SILK™), spin-on silicone based polymeric dielectric (e.g., hydrogen silsesquioxane (HSQ) and methylsilsesquioxane (MSQ) and combinations thereof.

The dielectric spacer 7 may be formed by deposition and etching. The width of the dielectric spacer 7 should be sufficiently wide enough so that the source and drain implants do not encroach significantly into the channel portion of the substrate 5 to cause short channel effects. In one embodiment, the dielectric spacer 7 has a width ranging from 5 nm to 20 nm. In another embodiment, the dielectric space 7 may have a width ranging from 2 nm to 30 nm. Although only one dielectric spacer 7 is depicted adjacent to each of the sacrificial gate structures 5, it is noted that any number of dielectric spacers may be present.

Following dielectric spacer 7 formation, a higher energy ion implant may be conducted to form deep source and drain regions (not shown). These implants are conducted at a higher energy and higher concentration of dopant than the implant for the source and drain extension regions 6. The deep source and drain regions are typically doped with a conductivity type consistent with the source and drain extension regions 6. In some embodiments, the deep source and drain regions, and source and drain extension regions 6, are activated by activation annealing. Activation anneal may be conducted at a temperature ranging from 850° C. to 1350° C.

In some embodiments, an etch stop liner 8 can be formed on at least the exterior surface Si of the dielectric spacer 7. The “exterior surface” refers to the outside sidewall of the dielectric spacer 7 that is opposite the sidewall of the dielectric spacer 7 that is in direct contact with the sacrificial gate structures 5. The etch stop liner 8 may be composed of a metal oxide. For example, and in some embodiments, the etch stop liner 8 may be composed of a metal oxide that is selected from the group consisting of zirconium oxide, aluminum oxide, magnesium oxide, hafnium oxide, lanthium oxide, cerium oxide, strontium oxide, titanium oxide and a combination thereof. In one embodiment, the etch stop liner 8 is a conformal layer that is formed using a conformal deposition process. The term “conformal” denotes a layer having a thickness that does not deviate from greater than or less than 30% of an average value for the thickness of the layer.

In one embodiment, the etch stop liner 8 is formed using a physical vapor deposition (PVD) process, such as sputtering. As used herein, “sputtering” means a method for depositing a film of metallic material, in which a target of the desired material, i.e., source, is bombarded with particles, e.g., ions, which knock atoms from the target, where the dislodged target material deposits on a deposition surface. Examples of sputtering apparatus that may be suitable for depositing the etch stop liner 8 include DC diode type systems, radio frequency (RF) sputtering, magnetron sputtering, and ionized metal plasma (IMP) sputtering. In one example, an etch stop liner 8 composed of hafnium oxide (HfO₂) is sputtered from a solid hafnium target, in which the oxygen content of the etch stop liner 8 is introduced by an oxygen containing gas. In another embodiment, the etch stop liner 8 is formed using a deposition process, such as chemical vapor deposition (CVD). Variations of chemical vapor deposition (CVD) processes for depositing the etch stop liner 8 include, but are not limited to, Atomic Layer CVD (ALD), Molecular Layer CVD (MLD), Atmospheric Pressure CVD (APCVD), Low Pressure CVD (LPCVD) and Plasma Enhanced CVD (PECVD), Metal-Organic CVD (MOCVD) and others. One example of a conformal deposition process is plasma enhanced chemical vapor deposition (PECVD). In another embodiment, the etch stop liner 8 may be formed by a thermal growth process such as, for example, oxidation, nitridation or oxynitridation.

In one embodiment, the etch stop liner 8 may have a thickness ranging from 1 nm to 20 nm. In another embodiment, the etch stop liner 8 may have a thickness ranging from 1 nm to 10 nm. In yet another embodiment, the etch stop liner 8 may have a thickness ranging from 1 nm to 20 nm.

In one embodiment, the horizontal surfaces of the etch stop liner 8, e.g., the portions of the etch stop liner 8 that are present on the upper surface of the substrate 10 between the sacrificial gate structures 5, may be removed by an etch process. In one example, the horizontal surfaces of the etch stop liner 8 may be removed with an anisotropic etch, while the portions of the etch stop liner 8 that are present on the exterior surfaces Si of the dielectric spacer 7 are protected by an etch mask, e.g., photoresist mask. It is noted that the etch stop liner 8 may be formed before or after either the deep source and drain regions or the source and drain extension regions 6.

Metal semiconductor alloy contacts (not shown) may be formed on an upper surface of the deep source and drain regions and the source and drain extension regions 6. In one embodiment, the metal semiconductor alloy contacts are composed of a silicide. Silicide formation includes forming a metal capable of reacting with silicon (Si) atop the entire structure, heating the structure to form a silicide, removing non-reacted metal, and, if needed, conducting a second heating step.

Still referring to FIG. 1, an intralevel dielectric 9 can be formed on the substrate 10 having an upper surface that is coplanar with an upper surface of the sacrificial gate structures 5. The intralevel dielectric 9 may be blanket deposited atop the entire substrate 10 and planarized. The blanket dielectric may be selected from the group consisting of silicon-containing materials such as SiO₂, Si₃N₄, SiOₓN_{y}, SiC, SiCO, SiCOH, and SiCH compounds, the above-mentioned silicon-containing materials with some or all of the Si replaced by Ge, carbon-doped oxides, inorganic oxides, inorganic polymers, hybrid polymers, organic polymers such as polyamides or SiLK™, other carbon-containing materials, organo-inorganic materials such as spin-on glasses and silsesquioxane-based materials, and diamond-like carbon (DLC, also known as amorphous hydrogenated carbon, α-C:H). Additional choices for the intralevel dielectric 9 include any of the aforementioned materials in porous form, or in a form that changes during processing to or from being porous and/or permeable to being non-porous and/or non-permeable.

The intralevel dielectric 9 may be formed using a deposited process, such as chemical vapor deposition (CVD). Variations of CVD processes that are suitable for forming the intralevel dielectric 9 include, but are not limited to, Atmospheric Pressure CVD (APCVD), Low Pressure CVD (LPCVD) and Plasma Enhanced CVD (PECVD), Metal-Organic CVD (MOCVD) and combinations thereof may also be employed. The intralevel dielectric 9 may also be deposited using evaporation, chemical solution deposition, spin on deposition, and physical vapor deposition (PVD) methods. Following deposition, the intralevel dielectric 9 may be planarized so that the upper surface of the intralevel dielectric layer 9 is coplanar with the upper surface of the sacrificial gate structures 5, as depicted in FIG. 1. Planarization is a material removal process that employs at least mechanical forces, such as frictional media, to produce a planar surface. The intralevel dielectric 9 may be planarized using chemical mechanical planarization (CMP). Chemical mechanical planarization (CMP) is a material removal process using both chemical reactions and mechanical forces to remove material and planarize a surface.

FIG. 2 depicts one embodiment of removing the sacrificial gate structures 5 to provide openings 2 to exposed portions, e.g., channel portions, of the substrate 10. The sacrificial gate structures 5 are typically removed using a selective etch process that removes the sacrificial gate structures 5 selectively to the substrate 10, the dielectric spacer 7 and the intralevel dielectric 9. The etch may be an isotropic etch or an anisotropic etch. The anisotropic etch may include reactive-ion etching (RIE). Other examples of anisotropic etching that can be used at this point of the present disclosure include ion beam etching, plasma etching or laser ablation. In comparison to anisotropic etching, isotropic etching is non-directional. One example of an isotropic etch is a wet chemical etch. In one embodiment, in which the sacrificial gate structures 5 are composed of polysilicon, the substrate 10 is a silicon-containing material, the dielectric spacer 7 is composed of nitride (Si₃N₄), and the intralevel dielectric 9 is composed of nitride (Si₃N₄), the wet etch chemistry for removing the sacrificial gate structures 5 may be composed of DHF and hot NH₃ or TetraMethyl Ammonium Hydroxide (TMAH).

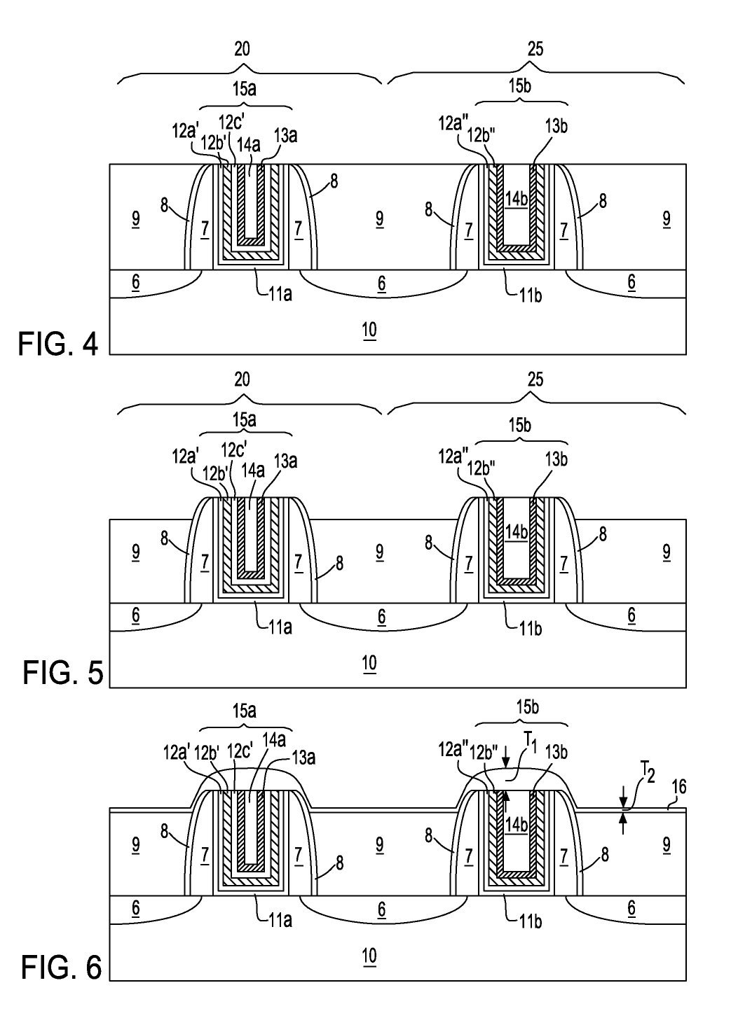

FIGS. 3 and 4 depict one embodiment of forming a functional gate structures 15 in the openings to the channel portions of the substrate 10. The functioning gate structures 15 are the structures used to control output current, i.e., flow of carriers in the channel, of the semiconducting devices, such as a field effect transistor (FET), through electrical or magnetic fields. In the embodiment depicted in FIGS. 3 and 4, a functional gate structure 15a of a first semiconductor device region 20 includes a first gate stack, and a functional gate structure 15b of a second semiconductor device region 25 includes a second gate stack, in which the first gate stack and the second gate stack have a different number of material layers. For example, and in one embodiment, in which the first semiconductor device region 20 is processed to provide an p-type field effect transistor, the first gate stack of the functional gate structure 15a may include a gate dielectric 11a that is composed of hafnium oxide (HfO₂); a metal nitride layer stack that includes a first titanium nitride (TiN) layer 12a′ on the gate dielectric 11a, a tantalum nitride (TaN), tantalum carbide (TaC), titanium carbide (TiC), and/or its alloy layer 12b′ that is present on the titanium nitride (TiN) layer 12a′, and a second titanium nitride (TiN) layer 12c′ that is present on the titanium nitride (TiN) layer 12a′; a titanium aluminum (TiAl) layer 13a, and an aluminum containing fill 14a. For example, and in one embodiment, in which the second semiconductor device region 25 is processed to provide an n-type field effect transistor, the second gate stack of the functional gate structure 15b may include a gate dielectric 11b that is composed of hafnium oxide (HfO₂); a metal nitride layer stack that includes a first titanium nitride (TiN) layer 12a″ on the gate dielectric 11b, a tantalum nitride (TaN) layer 12b″ that is present on the titanium nitride (TiN) layer 12a″, and a second titanium nitride (TiN) layer 12c″ that is present on the titanium nitride (TiN) layer 12a″; a titanium aluminum (TiAl) layer 13b, and an aluminum containing fill 14b. In some embodiments, an interfacial dielectric layer (not shown) composed of an oxide may be present between the gate dielectrics 11a, 11b and the substrate 10.

In one embodiment, the interfacial dielectric layer (not shown) is formed on the channel portion of the substrate 5 that is exposed by the opening, and a gate dielectric layer 11 is formed on the interfacial dielectric layer. In some embodiments, the interfacial dielectric layer may be removed, wherein the gate dielectric layer 11 is in direct contact with the channel portion of the substrate 10, as depicted in FIG. 3. The term “direct contact” means that a first element, such as a first structure, and a second element, such as a second structure, are connected without any intermediary conducting, insulating or semiconductor layers at the interface of the two elements. The terms “overlying”, “atop”, “positioned on” or “positioned atop” means that a first element, such as a first structure, is present on a second element, such as a second structure, wherein intervening elements may be present between the first element and the second element. When present, the interfacial dielectric layer is typically provided by thermal oxidation of the exposed surface of the substrate 10. In one embodiment, thermal oxidation of silicon is performed in the presence of oxygen at a temperature between 800° C. and 1200° C. In some examples, the oxidant may be either water vapor (steam) or molecular oxygen.

In one embodiment the gate dielectric layer 11 may be composed of a high-k dielectric material (and is hereafter referred to as a high-k gate dielectric layer 11). The term “high-k” refers to a dielectric material having a dielectric constant that is greater than 4.0 at room temperature, i.e., 20° C. to 25° C. The high-k gate dielectric layer 11 may be blanket deposited atop the structure depicted in FIG. 2. In one embodiment, the high-k gate dielectric layer 11 may be deposited on the channel portions of the substrate 5, the sidewalls of the dielectric spacer 7 and the upper surfaces of the intralevel dielectric 9. In some embodiments, the high-k gate dielectric layer 11 may be composed of an oxide, a nitride, an oxynitride or combinations and multi-layers thereof. Although the high-k gate dielectric may be any material having a dielectric constant that is greater than 4.0, e.g., 4.1, in some examples the high-k gate dielectric layer 11 is comprised of a material having a dielectric constant greater than 7.0. In another example, the high-k gate dielectric layer 11 is comprised of a material having a dielectric constant ranging from 4.0 to 30. The dielectric constants mentioned herein are relative to a vacuum at room temperature, i.e., 20° C. to 25° C. Some examples of suitable materials for the high-k gate dielectric layer 11 include hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, lead zinc niobate and combinations thereof. In one example, the high-k gate dielectric layer 11 is hafnium oxide (HfO₂).

In one embodiment, the high-k gate dielectric layer 11 may be a conformal layer that is formed using a conformal deposition process. In one embodiment, the high-k gate dielectric layer 11 can be formed using a deposition process, such as chemical vapor deposition (CVD). In another embodiment, the high-k gate dielectric 11 may be formed by a thermal growth process such as, for example, oxidation, nitridation or oxynitridation. The high-k gate dielectric layer 11 may have a thickness ranging from 1 nm to 5 nm. In another embodiment, the high-k gate dielectric layer 11 has a thickness ranging from 1 nm to 2.5 nm. In yet another example, the high-k gate dielectric layer 11 has a thickness that ranges from 15 Å to 20 Å.

FIG. 3 also depicts forming a metal nitride stack 12 and titanium aluminum (TiAl) layer 13 on the high-k gate dielectric layer 11. In some embodiments, at least one of the metal nitride stack 12 and the titanium aluminum (TiAl) may include at least one n-type or p-type work function metal. As used herein, an “n-type work function metal layer” is a metal layer that effectuates an n-type threshold voltage shift. “N-type threshold voltage shift” as used herein means a shift in the Fermi energy of an n-type semiconductor device towards a conduction band of silicon in a silicon-containing substrate of the n-type semiconductor device. The “conduction band” is the lowest lying electron energy band of the doped material that is not completely filled with electrons. In one embodiment, the work function of the n-type work function metal layer ranges from 4.1 eV to 4.3 eV. In one embodiment, the n-type work function metal layer is composed of at least one of TiAl, TanN, TiN, HfN, HfSi, or combinations thereof. As used herein, a “p-type work function metal layer” is a metal layer that effectuates a p-type threshold voltage shift. In one embodiment, the work function of the p-type work function metal layer 24 ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the Fermi energy of a p-type semiconductor device towards a valence band of silicon in the silicon containing substrate of the p-type semiconductor device. A “valence band” is the highest range of electron energies where electrons are normally present at absolute zero. In one embodiment, the p-type work function metal layer may be composed of titanium and their nitrided/carbide. In one embodiment, the p-type work function metal layer is composed of titanium nitride (TiN). The p-type work function metal layer may also be composed of TiAlN, Ru, Pt, Mo, Co and alloys and combinations thereof.

In the embodiment that is depicted in FIG. 3, the metal nitride stack 12 includes a first titanium nitride (TiN) layer 12a′ on the high-k gate dielectric 11, a tantalum nitride (TaN) layer 12b that is present on the titanium nitride (TiN) layer 12a, and a second titanium nitride (TiN) layer 12c that is present on the titanium nitride (TiN) layer 12a. Each metal nitride layer of the metal nitride stack 12 may be deposited using a physical vapor deposition (PVD) method, such as sputtering. Examples of sputtering apparatus that may be suitable for depositing the metal nitride layers of the metal nitride stack 12 include DC diode type systems, radio frequency (RF) sputtering, magnetron sputtering, and ionized metal plasma (IMP) sputtering. In one example, a metal nitride is sputtered from a solid metal target, such as a titanium solid target, in which the nitrogen content of the metal nitride layer is introduced by a nitrogen gas. In another example, the metal nitride layers of the metal nitride stack 12 are sputtered from a solid target comprised of a metal and nitrogen, such as a solid target of titanium nitride. In addition to physical vapor deposition (PVD) techniques, the metal nitride stack 12 may also be formed using chemical vapor deposition (CVD) and atomic layer deposition (ALD). The metal nitride layers 12a, 12b, 12c of the metal nitride stack 12 may each have a thickness ranging from 1 nm to 5 nm. In another embodiment, the metal nitride layers 12a, 12b, 12c of the metal nitride stack 12 may each have a thickness ranging from 1 nm to 2.5 nm. In yet another example, the metal nitride layers 12a, 12b, 12c of the metal nitride stack 12 may each have a thickness that ranges from 15 Å to 20 Å.

In some embodiments before depositing the titanium aluminum (TiAl) layer 13, the second metal nitride layer 12c may be removed from the second semiconductor device region 25. A portion of the second metal nitride layer 12c may be removed using photolithography and etch processes. For example, following the deposition of the second metal nitride layer 12c, an etch mask, (not shown), can be formed atop the second metal nitride layer 12c protecting the portion of the second metal nitride layer 12c that is present in the first semiconductor device region 20, wherein the portions of the second metal nitride layer 12c exposed by the etch mask are removed by an etch process, such as an anisotropic etch process, e.g., reactive ion etch. In one embodiment, the etch mask may be provided by a patterned photoresist layer. The remaining portion of the second metal nitride layer 12c provides a component of the metal nitride stack for the functional gate structure of the semiconductor devices that are formed within first semiconductor device region 20.

In a following step, the titanium aluminum (TiAl) layer 13 can be blanket deposited on the first and second semiconductor device regions 20, 25 of the substrate 10. The titanium aluminum (TiAl) layer 13 may be deposited using physical vapor deposition (PVD), such as sputtering or plating. Examples of sputtering apparatus that may be suitable for depositing the titanium aluminum (TiAl) layer 13 include DC diode type systems, radio frequency (RF) sputtering, magnetron sputtering, and ionized metal plasma (IMP) sputtering. The titanium aluminum (TiAl) layer 13 may have a thickness ranging from 1 nm to 5 nm. In another embodiment, the titanium aluminum (TiAl) layer 13 may have a thickness ranging from 1 nm to 2.5 nm. In yet another example, the titanium aluminum (TiAl) layer 13 may have a thickness that ranges from 15 Å to 20 Å.

The metal nitride stack 12 and the titanium aluminum (TiAl) layer 13 may each be conformally deposited layers that are formed on the base and sidewalls of the openings that are formed by removing the sacrificial gate structures 5. Typically, the metal nitride stack 12 and the titanium aluminum (TiAl) layer 13 do not fill the entirety of the openings that are formed by removing the sacrificial gate structures 5. In some embodiments, an aluminum containing fill 14 is deposited on the titanium aluminum (TiAl) layer to fill the openings. The aluminum containing fill 14 may be entirely composed of aluminum with incidental impurities. For example, the aluminum containing fill 14 may be 99 wt. % aluminum. In other examples, the aluminum containing fill 14 may be alloyed with other metals and semiconductor materials. The aluminum containing fill 14 may be deposited using a physical vapor deposition (PVD) method, such as sputtering or plating.

FIG. 4 depicts one embodiment of planarizing the material layers, i.e., the high-k gate dielectric layer 11, the metal nitride stack 12, the titanium aluminum layer 12 and the aluminum containing fill 14, that provide the functional gate structures 15a, 15b until the upper surfaces of the functional gate structures 15a, 15b are coplanar with an upper surface of an intralevel dielectrics 9 that are adjacent to each the functional gate structures 15a, 15b. “Planarization” is a material removal process that employs at least mechanical forces, such as frictional media, to produce a planar surface. In one embodiment, the planarization process includes chemical mechanical polishing (CMP) or grinding. Chemical mechanical planarization (CMP) is a material removal process using both chemical reactions and mechanical forces to remove material and planarize a surface. In one embodiment, the planarization process removes the portion of the high-k gate dielectric layer 11, the metal nitride stack 12, the titanium aluminum layer 12 and the aluminum containing fill 14 that is present on the upper surface of the intralevel dielectric 90. Following planarization, a first portion of the high-k gate dielectric 11a is present in the first semiconductor device region 20 and a second portion of the high-k gate dielectric layer 11b is present in the second semiconductor device region 25.

FIG. 5 depicts recessing the intralevel dielectric 9 selectively to the functional gate structures 15a, 15b. In one embodiment, the intralevel dielectric 9 may be etched selectively to the etch stop liner 8 that is present on the exterior surface Si of the dielectric spacers 7. The etch process for recessing the intralevel dielectric 9 may be a wet etch, such as wet chemical etch, or a dry etch, such as reactive ion etch (RIE). The intralevel dielectric 9 may be recessed to a height that exposes the upper surface of the functional gate structures 15a, 15b. In one example, in which the intralevel dielectric 9 is composed of silicon oxide (SiO₂) and the etch stop liner 8 is composed of hafnium oxide (HfO₂) and the intralevel dielectric 9 is composed of silicon nitride (Si₃N₄), the etch chemistry for recessing the intralevel dielectric 9 is composed of CF₄.

FIG. 6 depicts one embodiment of depositing a metal layer 16 for the metal gate caps on the upper surfaces of the functional gate structures 15a, 15b and on an upper surface of the intralevel dielectric 9. The metal layer 16 may be composed of any metal that provides for selective deposition onto the metal elements of the functional gate structures 15a, 15b. By “selective deposition” it is meant that a deposition process deposits a material on a first type deposition surface at a greater rate of deposition than a second type deposition surface. For example, the metal that provides the metal layer 16 may have a greater deposition rate on a metal surface, such as the upper surface of the functional gate structures 15a, 15b, than the deposition rate of the metal on the dielectric surface, such as the intralevel dielectric 9. In one embodiment, the metal of the metal layer 16 may be selected from the group consisting of cobalt (Co), hafnium (Hf), aluminum (Al), nickel (Ni), titanium (Ti), tantalum (Ta), and a combination thereof. The metal layer 16 may be deposited using a physical vapor deposition (PVD) method, such as plating or sputtering. Examples of sputtering apparatus that may be suitable for depositing the metal layer 16 include DC diode type systems, radio frequency (RF) sputtering, magnetron sputtering, and ionized metal plasma (IMP) sputtering. In addition to physical vapor deposition (PVD) techniques, the metal layer 16 may also be formed using chemical vapor deposition (CVD) and atomic layer deposition (ALD).

The metal layer 16 may have a first thickness T1 on each of the upper surface of the functional gate structures 15a, 15b that ranges from 1 nm to 20 nm. In another embodiment, the metal layer 16 may have a first thickness T1 on the upper surface of each of the functional gate structures 15a, 15b that ranges from 10 nm to 100 nm. The metal layer 16 may have a second thickness T2 on the upper surface of the intralevel dielectric 9 that ranges from 1 nm to 20 nm. In another embodiment, the metal layer 16 may have a second thickness T2 on the upper surface of the intralevel dielectric 9 that ranges from 10 nm to 100 nm.

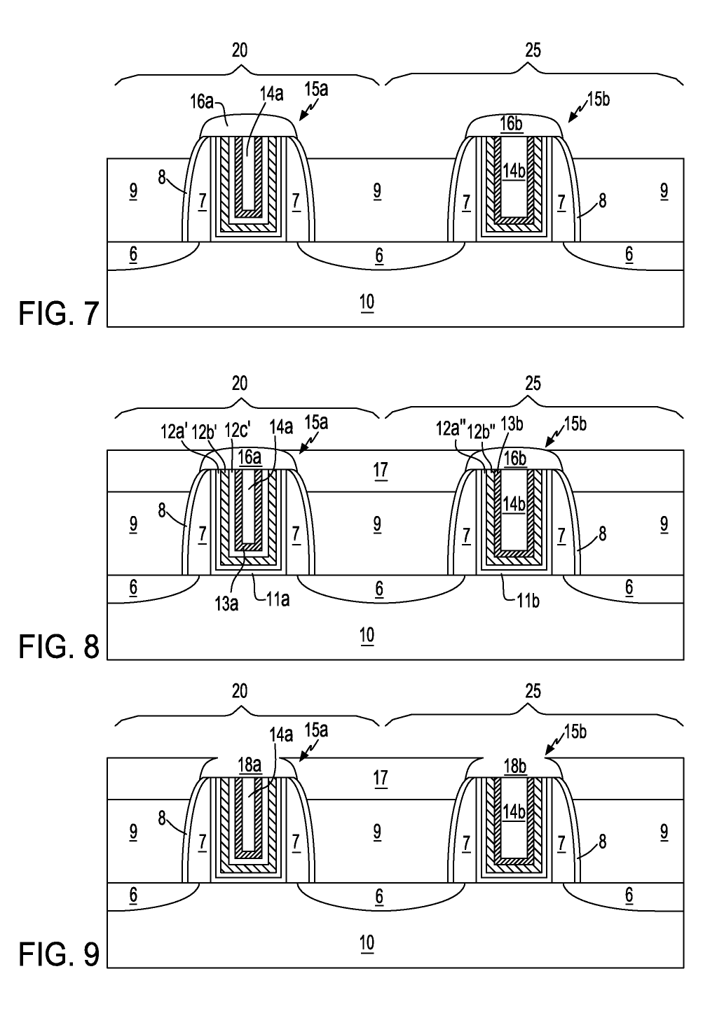

FIG. 7 depicts one embodiment of removing the metal layer 16 that is present upper surface of the intralevel dielectric 9, wherein the remaining portion of the metal layer 16 that is present on the functional gate structures 15a, 15b provides the metal gate caps 16a, 16b. In one embodiment, the metal layer 16 can be removed from the upper surface of the intralevel dielectric 9 using an isotropic etch. Contrary to an anisotropic etch that has a etch rate in one direction that is greater than the other directions, an isotropic etch has substantially the same etch rate in all directions. In one embodiment, the isotropic etch may be provided by a dry etch, such as reactive ion etch (RIE). The etch process may be a highly selective etch process, such as an etch for removing oxide selectively to other materials, such as SiCoNi, as disclosed in US Application Publication No. 2011/0151674, or the etch process may be a COR etch (chemical oxide removal). The etch process for removing the metal layer 16 that is present on the upper surface of the intralevel dielectric 9 should be timed so that a portion of the metal layer 16 remains atop the functional gate structures 15a, 15b to provide the metal gate caps 16a, 16b. Because there is a greater thickness of material for the metal layer 16 that is present over the functional gate structures 15a, 15b than the thickness of the metal layer 16 that is present over the intralevel dielectric 9, the metal layer 16 that is present over the intralevel dielectric 9 may be removed in its entirety while a remaining portion of the metal layer 16 is still present on the upper surface of the functional gate structures 15a, 15b to provide the metal gate caps 16a, 16b.

FIG. 8 depicts one embodiment of forming a dielectric cap 17 on the recessed upper surface of the intralevel dielectric 9. The dielectric cap 17 may be blanket deposited over the entire substrate 10 and planarized to have an upper surface with the metal gate caps 16a, 16b. The dielectric cap 17 may be selected from the group consisting of silicon-containing materials such as SiO₂, Si₃N₄, SiOₓN_{y}, SiC, SiCO, SiCOH, and SiCH compounds, the above-mentioned silicon-containing materials with some or all of the Si replaced by Ge, carbon-doped oxides, inorganic oxides, inorganic polymers, hybrid polymers, organic polymers such as polyamides or SiLK™, other carbon-containing materials, organo-inorganic materials such as spin-on glasses and silsesquioxane-based materials, and diamond-like carbon (DLC, also known as amorphous hydrogenated carbon, α-C:H). Additional choices for the dielectric cap 17 includes any of the aforementioned materials in porous form, or in a form that changes during processing to or from being porous and/or permeable to being non-porous and/or non-permeable.

The dielectric cap 17 may be formed using a deposited process, such as chemical vapor deposition (CVD). Variations of CVD processes that are suitable for forming the intralevel dielectric 9 include, but are not limited to, Atmospheric Pressure CVD (APCVD), Low Pressure CVD (LPCVD) and Plasma Enhanced CVD (EPCVD), Metal-Organic CVD (MOCVD) and combinations thereof may also be employed. The dielectric cap 17 may also be deposited using evaporation, chemical solution deposition, spin on deposition, and physical vapor deposition (PVD) methods. Following deposition, the dielectric cap 17 may be planarized so that the upper surface of the dielectric cap 17 is coplanar with the upper surface of the metal gate caps 16a, 16b, as depicted in FIG. 8. The dielectric cap 17 may be planarized using chemical mechanical planarization (CMP).

FIG. 9 depicts removing the metal gate caps 16a, 16b to form a void 18a, 18b over each of the function gate structures 15a, 15b. In one embodiment, the metal gate caps 16a, 16b may be removed by an etch that is selective to the dielectric cap 17 and the metal of the function gate structures 15a, 15b. In one embodiment, the etch process for removing the metal gate caps 16a, 16b is a dry etch, such as reactive ion etch (RIE). In one example, in which the metal gate caps 16a, 16b are composed of oxidized cobalt, oxidized hafnium, oxidized aluminum, oxidized titanium and oxidized tantalum, and the dielectric cap 17 is composed of silicon-containing materials such as SiO₂, Si₃N₄, SiOₓN_{y}, SiC, SiCO, SiCOH, and SiCH compounds, the etch chemistry for removing the metal gate caps may be Cl₂, BCl₃, CF₄, SF₆.

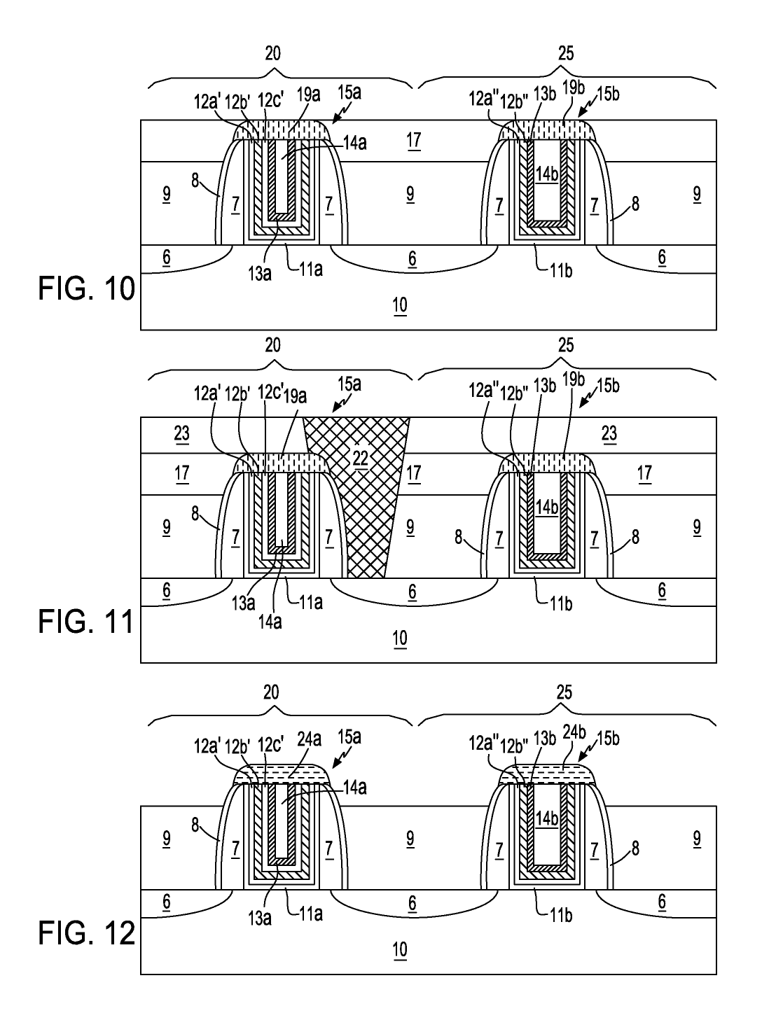

FIG. 10 depicts one embodiment of filling the voids formed by removing the metal gate caps 16a, 16b that were present over the functional gate structures 15a, 15b with metal oxide caps 19a, 19b. The metal oxide caps 19a, 19b may be composed of hafnium oxide (HfO₂), aluminum oxide (Al₂O₃), zirconium oxide (ZrO₂), tantalum oxide (Ta₂O₅), titanium oxide (TiO₂) cobalt oxide (Co₂O₃), cerium oxide (CeO₂), nickel oxide (NiO) and a combination thereof. The metal oxide caps 19a, 19b may be formed using chemical vapor deposition (CVD) and physical vapor deposition (PVD) methods. Examples of physical vapor deposition (PVD) methods that are suitable for forming the metal oxide caps 19a, 19b include plating and sputtering. Examples of sputtering apparatus that may be suitable for depositing the metal oxide caps 19a, 19b include DC diode type systems, radio frequency (RF) sputtering, magnetron sputtering, and ionized metal plasma (IMP) sputtering. Variations of CVD processes that are suitable for forming the metal oxide caps 19a, 19b include, but are not limited to, Atmospheric Pressure CVD (APCVD), Low Pressure CVD (LPCVD) and Plasma Enhanced CVD (EPCVD), Metal-Organic CVD (MOCVD) and combinations thereof may also be employed. The metal oxide caps 19a, 19b may also be deposited using evaporation, chemical solution deposition and spin on deposition.

In some embodiments, after forming the metal oxide caps 19a, 19b, another dielectric layer, such as an interlevel dielectric 23, may be formed atop the dielectric cap 17 and the intralevel dielectric 9, as depicted in FIG. 11. The interlevel dielectric 23 may be composed of the same or of a different composition dielectric material as the dielectric cap 17. Further, the interlevel dielectric 23 may be formed using a deposition process that is similar to the deposition processes that are used to provide the dielectric cap 17 and the intralevel dielectric 9. Therefore the above description of the dielectric cap 17 and the intralevel dielectric 9 are suitable for the interlevel dielectric 23.

Referring to FIG. 11 and, in one embodiment, the interlevel dielectric 23, dielectric cap 17 and the intralevel dielectric 9 can be patterned and etched to provide an opening 21 (also referred to as via holes 21) to at least one of the source and drain extension regions 6 that are present on opposing sides of the channel portion of the substrate 10. In one embodiment, the interlevel dielectric 23, the dielectric cap 17 and the intralevel dielectric 7 can be etched to provide the via holes 21 using an etch process that is selective to the metal oxide caps 19a, 19b. In one embodiment, the a photoresist etch mask (not shown) can be produced by applying a photoresist layer to the surface of the interlevel dielectric 23, exposing the photoresist layer to a pattern of radiation, and then developing the pattern into the photoresist layer utilizing a resist developer. The photoresist etch mask may be positioned so that the gate conductors of the functional gate structures 15a, 15b are not entirely protected by the photoresist etch mask. The etch that forms the via holes 21 to the source and drain regions, i.e., source and drain extension regions 6 and deep source and drain regions, may be selective to the metal oxide caps 19a, 19b and the etch stop liner 8 that is present on the exterior surface of the dielectric spacers 7. Therefore, the etch does not damage the functional gate structures 15a, 15b and/or the dielectric spacers 7. Because the etch process that is forming the via holes 21 is selective to the metal oxide caps 19a, 19b and the etch stop liner 8, it is not critical that the photoresist etch mask be aligned to protect the underlying functional gate structures 15a, 15b.

Following formation of the photoresist etch mask, the exposed portion of the interlevel dielectric 23, the dielectric cap 17 and the intralevel dielectric 9 can then be removed by a selective etch. The selective etch may be an anisotropic etch or an isotropic etch. In one example, when the interlevel dielectric layer 23, the dielectric cap 17 and the intralevel dielectric 9 are composed of silicon nitride, the metal oxide caps 19a, 19b are composed of hafnium oxide (HfO₂), the etch stop liner 8 is composed of hafnium oxide (HfO₂), and the substrate 10 is composed of silicon, the etch chemistry for forming the via holes 21 to the source and drain regions, i.e., source and drain extension regions 6 and deep source and drain regions, may be composed of fluorine based chemical, such as CF₄, CClF₂, SF₆ and combinations thereof. Following via hole 21 formation, interconnects 22 (hereafter referred to as “contacts”) can be formed by depositing a conductive metal into the via holes 21 using deposition methods, such as CVD or plating. The conductive metal may include, but is not limited to, tungsten, copper, aluminum, silver, gold, and alloys thereof.

FIGS. 1-7, 11 and 12 depict another embodiment of the present disclosure for forming contacts to the source and drain regions of a semiconductor device. The initial process steps for forming the structure depicted in FIG. 12 are similar to the process sequence that is described above with reference to FIGS. 1-7. In this embodiment, the method may begin with forming functional gate structures 15a, 15b having metal gate conductors 11a, 11b, 12a′, 12a″, 12b′, 12b″, 12c′, 13a, 13b, 14a, 14b on channel portion of a substrate 10. The functional gate structures 15a, 15b, and their method of formation, have been described above with reference to FIGS. 1-4. In a following process step, metal gate caps 16a and 16b may be formed on an upper surface of the functional gate structures 15a, 15b, as described with reference to FIGS. 5-7. Turning to FIG. 12, the metal gate caps 16a, 16b may then be oxidized into metal oxide caps 24a, 24b. The metal gate caps 16a, 16b may be oxidized by exposure to an oxygen containing gas or plasma. The metal gate caps 16a, 16b may be oxidized by thermal oxidation. In one embodiment, thermal oxidation of metal gate caps 16a, 16b can be performed in the presence of oxygen at a temperature between 300° C. and 1200° C. In some examples, the oxidant may be either water vapor (steam) or molecular oxygen. In one embodiment, the composition of the metal oxide caps 24a, 24b may be selected from the group consisting of aluminum oxide (Al₂O₃), hafnium oxide (HfO₂), magnesium oxide (MgO₂), cerium oxide (CeO₂), cobalt oxide (Co₂O₃), aluminum oxide (Al₂O₃), Nickel oxide (NiO) or a combination thereof. Following the formation of the metal oxide caps 24a, 24b, the process flow may continued with forming an interlevel dielectric 23 on the metal gate cap 24a, 24b and the intralevel dielectric 9; and etching the interlevel dielectric layer 23 and the intralevel dielectric 9 using an etch chemistry that is selective to the metal oxide cap 24a, 24b to provide an opening, i.e., via opening 21, to at least one of a source region and a drain region, as described with reference to FIG. 11. Still referring to FIG. 11, the method may continue with filling the via openings 21 with a metal to provide contacts 22 to at least one of the source region and the drain region.

While the present disclosure has been particularly shown and described with respect to preferred embodiments thereof, it will be understood by those skilled in the art that the foregoing and other changes in forms and details may be made without departing from the scope and spirit of the present disclosure. It is therefore intended that the present disclosure not be limited to the exact forms and details described and illustrated, but fall within the scope of the appended claims.

1. A method of forming contacts to a semiconductor device comprising:
providing a gate structure having a metal gate conductor on the channel portion of a substrate, wherein an intralevel dielectric is present on the substrate adjacent to the gate structure;
forming a metal gate cap on the upper surface of the metal gate conductor;
forming a dielectric cap on the intralevel dielectric;
removing the metal gate cap selectively to the dielectric cap and the metal gate conductor to provide a void overlying the metal gate conductor;
filling the void overlying the metal gate conductor with a metal oxide cap;
etching the dielectric cap and the intralevel dielectric using an etch chemistry that is selective to the metal oxide cap to provide an opening to at least one of a source region and a drain region that is present on opposing sides of the channel portion of the substrate; and
forming a metal fill in the opening to provide a contact to said at least one of the source region and the drain region, wherein the forming of the metal gate cap on the upper surface of the metal gate conductor comprises:
deposition of a metal on the upper surface of the metal gate conductor and an upper surface of the intralevel dielectric, wherein the thickness of the metal for the metal gate cap is greater on the metal gate conductor than the intralevel dielectric; and
etching the metal that is present on the intralevel dielectric with an isotropic etch.

2. The method of claim 1, wherein forming the gate structure comprises:
forming a sacrificial gate structure on the substrate;
forming the source region and the drain region in the substrate on opposing sides of the channel portion of the substrate;
forming the intralevel dielectric;
removing the sacrificial gate structure selectively to the intralevel dielectric to provide an opening to the channel portion of the substrate; and
forming the gate structure in the opening to the channel portion of the substrate.

3. The method of claim 2, wherein prior to forming the intralevel dielectric, a dielectric spacer is formed adjacent to the gate structure, and an etch stop liner is formed on at least an exterior surface of the dielectric spacer.

4. The method of claim 3, wherein the etch stop liner is composed of a metal oxide selected from the group consisting of zirconium oxide, aluminum oxide, magnesium oxide, hafnium oxide and a combination thereof.

5. The method of claim 3, wherein prior to forming the metal gate cap on the upper surface of the metal gate conductor, an upper surface of the intralevel dielectric is recessed selectively to the etch stop liner that is present on the dielectric spacer.

6. (canceled)

7. The method of claim 1, wherein the metal for the metal gate cap is selected from the group consisting of hafnium, titanium, tantalum, tungsten, zirconium and aluminum.

8. The method of claim 1, wherein the forming of the dielectric cap on the intralevel dielectric comprises depositing a dielectric material on the substrate and planarizing the dielectric material until an upper surface of the dielectric material for the interlevel dielectric is coplanar with an upper surface of the metal gate cap that is present on the metal gate conductor.

9. The method of claim 1, wherein the removing of the metal gate cap selectively to the dielectric cap and the metal gate conductor comprises a dry etch.

10. The method of claim 1, wherein the filling of the void with the metal oxide cap comprises depositing a metal oxide that is selected from the group consisting of zirconium oxide, aluminum oxide, magnesium oxide, hafnium oxide and a combination thereof.

11. The method of claim 1, wherein the forming of the metal fill in the opening to provide the contact to said at least one of the source region and the drain region comprises depositing a metal selected from the group consisting of copper, aluminum, titanium, tungsten, tantalum and a combination thereof.

12. A method of forming contacts to a semiconductor device comprising:
providing a gate structure having a metal gate conductor on the channel portion of a substrate, wherein an intralevel dielectric is present on the substrate adjacent to the gate structure;
forming a metal gate cap on the upper surface of the metal gate conductor;
oxidizing the metal gate cap to provide a metal oxide cap;
forming an interlevel dielectric layer on the metal oxide cap and the intralevel dielectric;
etching the interlevel dielectric layer and the intralevel dielectric using an etch chemistry that is selective to the metal oxide cap to provide an opening to at least one of a source region and a drain region that is present on opposing sides of the channel portion of the substrate; and
filling the opening with a metal that forms a contact to said at least one of the source region and the drain region,
wherein the forming of the metal gate cap on the upper surface of the metal gate conductor comprises:
deposition of a metal on the upper surface of the metal gate conductor and an upper surface of the intralevel dielectric, wherein the thickness of the metal for the metal gate cap is greater on the metal gate conductor than the intralevel dielectric; and
etching the metal that is present on the intralevel dielectric with an isotropic etch.

13. The method of claim 12, wherein forming the gate structure comprises:
forming a sacrificial gate structure on the substrate;
forming the source region and the drain region in the substrate on opposing sides of the channel portion of the substrate;
forming the intralevel dielectric;
removing the sacrificial gate structure selectively to the intralevel dielectric to provide an opening to the channel portion of the substrate; and
forming the gate structure in the opening to the channel portion of the substrate.

14. The method of claim 12, wherein prior to forming the intralevel dielectric, dielectric spacers are formed adjacent to the gate structure, and an etch stop liner is formed on at least an exterior surface of the dielectric spacers.

15. The method of claim 14, wherein the etch stop liner is composed of a metal oxide selected from the group consisting of zirconium oxide, aluminum oxide, magnesium oxide, hafnium oxide and a combination thereof.

16. The method of claim 14, wherein prior to forming the metal gate cap on the upper surface of the metal gate conductor, an upper surface of the intralevel dielectric is recessed selectively to the etch stop liner.

17. (canceled)

18. The method of claim 15, wherein the metal for the metal gate cap is selected from the group consisting of hafnium, titanium, tantalum, tungsten, zirconium and aluminum.

19. The method of claim 12, wherein the oxidizing of the metal gate cap to provide the metal oxide cap comprises applying an oxygen containing gas to the metal gate cap, applying a oxygen containing plasma to the metal gate cap, applying a thermal oxidation to the metal gate cap or a combination thereof.

20. The method of claim 12, wherein the metal oxide cap has a composition that is selected from the group consisting of zirconium oxide, aluminum oxide, magnesium oxide, hafnium oxide and a combination thereof.

21. The method of claim 12, wherein the forming of the metal fill in the opening to provide the contact to said at least one of the source region and the drain region comprises depositing a metal selected from the group consisting of copper, aluminum, titanium, tungsten, tantalum and a combination thereof.

22. (canceled)

23. (canceled)
